(19) United States
(12) Patent Application Publication
(10) Pub. No.: US 2025/0231049 A1
(43) Pub. Date: Jul. 17, 2025

(54) SYSTEMS, APPARATUSES, AND METHODS FOR OFF-AXIS MULTI-TURN POSITION SENSING

(71) Applicant: HONEYWELL INTERNATIONAL INC., Charlotte, NC (US)

(72) Inventors: Paresh SANCHIHAR, Charlotte, NC (US); John JERRED, Charlotte, NC (US); Kumaran S. NARASIMHAN, Charlotte, NC (US); Abhinav PANDEY, Charlotte, NC (US)

(21) Appl. No.: 19/007,016

(22) Filed: Dec. 31, 2024

(30) Foreign Application Priority Data
Jan. 15, 2024 (IN) 202411002833

(51) Int. Cl. G01D 5/16; G01R 33/09

(52) U.S. Cl. CPC G01D 5/16; G01R 33/091

(57) ABSTRACT

Various embodiments are directed to an off-axis multi-turn position measurement system comprising a magnet defining a magnetic surface comprising at least two magnetized poles arranged in a spiral pattern and an opening for receiving a rotatable component; and at least one magnetic field sensor assembly positioned proximate to the magnetic surface such that the at least one magnetic field sensor assembly is off-axis with respect to a center axis defined by the magnet. The magnet may be rotatable about the center axis relative to the at least one magnetic field sensor, the at least one multi-turn magnetic field sensor may be configured to generate at least a first output and a second output based on the magnetic field, and an angle position and turn count of the rotatable component may be determined based on the first output and the second output respectively.

### CROSS-REFERENCE TO RELATED APPLICATIONS

This application claims priority pursuant to 35 U.S.C. 119(a) to Indian Application No. 202411002833, filed Jan. 15, 2024, which application is incorporated herein by reference in its entirety.

### FIELD OF THE INVENTION

Various embodiments described herein relate generally to position measurement using magnetic field sensors, and more particularly to systems, apparatuses, and methods relating to off-axis multi-turn position measurement.

### BACKGROUND

It is often desirable in many applications to identify the position of a rotatable component (e.g., steering wheel shaft, cam shaft, or the like), as well as the number of turns of the rotatable component. Applicant has identified many technical challenges and difficulties associated with determining absolute angle position and turn count of rotatable components. Through applied effort, ingenuity, and innovation, many of these identified problems have been solved by developing solutions that are included in embodiments of the present disclosure, many examples of which are described in detail herein.

### BRIEF SUMMARY

Various embodiments described herein relate to off-axis multi-turn position measurement systems and methods. In accordance with various embodiments, an off-axis multi-turn position measurement system comprises a magnet defining (i) a magnetic surface comprising at least two magnetized poles arranged in a spiral pattern and (ii) an opening for receiving a rotatable component, wherein the magnet generates a magnetic field having varying magnetic field direction based on the spiral pattern of the magnet; and at least one magnetic field sensor assembly positioned proximate to the magnetic surface of the magnet such that the at least one magnetic field sensor assembly is off-axis with respect to a center axis defined by the magnet, wherein: the magnet is rotatable about the center axis relative to the at least one multi-turn magnetic field sensor assembly, the at least one magnetic field sensor assembly is configured to generate at least a first output and a second output based on the magnetic field generated by the magnet, an angle position of the rotatable component is determined based on the first output, and a turn count of the rotatable component is determined based on the second output.

In some embodiments, the at least one magnetic field sensor assembly comprises an angle position sensor configured to generate the first output and a multi-turn magnetoresistive sensor configured to generate the second output.

In some embodiments, the angle position sensor comprises a magnetoresistive sensor.

In some embodiments, the first output comprises a periodic position signals having N number of periods per revolution of the magnet.

In some embodiments, the magnet as M number of pole counts, wherein the N number of periods is based on one or more of the M number of pole counts or tilt angle of the at least two magnetized poles.

In some embodiments, the at least one magnetic field sensor assembly comprises a plurality of magnetic field sensor assemblies that are spaced apart around relative to and proximate to the magnetic surface of the magnet.

In some embodiments, the at least one magnetic field sensor assembly is configured to be substantially stationary.

In some embodiments, the at least one magnetic field sensor assembly is positioned proximate to the magnetic surface of the magnet such that the at least one magnetic field sensor assembly maintains a substantially constant air gap with respect to the magnetic surface during relative rotation of the magnet with respect to the at least one magnetic field sensor assembly.

In some embodiments, the rotatable component comprises a rotatable shaft.

In some embodiments, the off-axis multi-turn position measurement system further comprises a controller, wherein the first output and the second output of the at least one magnetic field sensor assembly is transmitted to the controller, and wherein the controller is configured to process the first output to determine the angle position and process the second output to determine the turn count.

In some embodiments, the at least two magnetized poles comprise alternating magnetic polarities.

In some embodiments, the at least two magnetized poles have the same width.

In accordance with various embodiments, an off-axis multi-turn position measurement system comprises a magnet defining (i) a magnetic surface comprising at least two magnetized poles arranged in a helical pattern and (ii) an opening for receiving a rotatable component, wherein the magnet generates a magnetic field having varying magnetic field direction based on the helical pattern of the magnet; and at least one magnetic field sensor assembly positioned proximate to the magnetic surface of the magnet such that the at least one magnetic field sensor assembly is off-axis with respect to a center axis the magnet, wherein: the magnet is rotatable about the center axis relative to the at least one magnetic field sensor assembly, the at least one magnetic field sensor assembly is configured to generate at least a first output and a second output based on the magnetic field generated by the magnet, an angle position of the rotatable component is determined based on the first output, and a turn count of the rotatable component is determined based on the second output.

In some embodiments, the at least one magnetic field sensor assembly comprises an angle position sensor configured to generate the first output and a multi-turn magnetoresistive sensor configured to generate the second output.

In some embodiments, the angle position sensor comprises a magnetoresistive sensor.

In some embodiments, the first output comprises a periodic position signals having N number of periods per revolution of the magnet.

In some embodiments, the magnet as M number of pole counts, wherein the N number of periods is based on one or more of the M number of pole counts or tilt angle of the at least two magnetized poles.

In accordance with various embodiments, a method for determining angle position and turn count of a rotatable component comprises: causing a magnet coupled to the rotatable component to rotate about a center of axis of the magnet relative to at least one magnetic field sensor assembly, wherein the magnet is coupled to the rotatable component via an opening defined by the magnet, and wherein the at least one magnetic field sensor assembly is configured to generate a first output and a second output based on a magnetic field generated by the magnet; and determining, based at least in part on the first output and the second output generated by the at least one multi-turn magnetic field sensor, angle position data and the turn count data of the rotatable component.

In some embodiments, the magnet comprises at least two magnetized poles arranged in a spiral pattern.

In some embodiments, the magnet comprises at least two magnetized poles arranged in a helical pattern.

### BRIEF DESCRIPTION OF THE DRAWINGS

Reference will now be made to the accompanying drawings, which are not necessarily drawn to scale, and wherein:

FIG. 1 schematically illustrates an example off-axis multi-turn position measurement system in accordance with various embodiments of the present invention.

FIG. 2 depicts a perspective view of an example radial spiral disk multipole magnet array in accordance with various embodiments of the present invention.

FIGS. 3A-3B depict plan views of example radial spiral disk multipole magnet array in accordance with various embodiments of the present invention.

FIGS. 4A-4F depict example radial spiral disk multipole magnet array having different pole counts in accordance with various embodiments of the present invention.

FIG. 5 depicts a perspective view of an example axial cylindrical helical multipole magnet array configuration in accordance with various embodiments of the present invention.

FIG. 6 illustrates an exemplary apparatus for implementing various embodiments of the present disclosure.

FIG. 7 depicts an example process flow chart for off-axis multi-turn position measurement in accordance with various embodiments of the present invention.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

It should be understood at the outset that although illustrative implementations of one or more aspects are illustrated below, the disclosed systems, and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents. While values for dimensions of various elements are disclosed, the drawings may not be to scale.

The words “example,” or “exemplary,” when used herein, are intended to mean “serving as an example, instance, or illustration.” Any implementation described herein as an “example” or “exemplary embodiment” is not necessarily preferred or advantageous over other implementations.

Described herein are example systems, apparatuses, and methods for determining the angle position of a rotatable component and turn count (e.g., number of revolutions) of the rotatable component. Various embodiments of the present disclosure may function as a multi-turn smart resolver for electrification. An example off-axis multi-turn position measurement system may be configured to provide a multi-turn true power off position sensing. An example off-axis multi-turn position measurement system according to various embodiments may leverage a magnet having magnetic pattern that defines a number of poles for a required angle, and at least one magnetic field sensor assembly for determining the angle position and turn count for a rotatable component based on magnetic field generated by the magnet.

In various embodiments, a magnetic field sensor assembly includes an angle position sensor and a multi-turn magnetoresistive sensor with true power off multi-turn sensing. By leveraging a magnetic field sensor assembly that includes a multi-turn magnetoresistive sensor with true power off multi-turn sensing, various embodiments of the present disclosure obviate the need for complex turn count solution (such as complex gear trains, for example), which in turn improves packaging and reduces cost.

According to various embodiments, the magnetic field sensor assembly is positioned relative and proximate to the magnet in an off-axis configuration, such that the magnetic field sensor assembly is not concentric with the center axis defined by the magnet. In various embodiments, the noted off-axis configuration allows for multiple magnetic field sensor assemblies to be positioned around the rotatable component (e.g., steering wheel shaft, cam shaft, or the like) while providing access to the rotatable component. By allowing for multiple magnetic field sensor assemblies to be positioned around the rotatable component (e.g., as opposed to directly on the rotatable component), various embodiments of the present disclosure provide for direct measurement of the system being driven by the rotatable component, improved packaging, redundancy, improved measurement accuracy, improved reliability, and improved packaging (e.g., (e.g., compact packaging). Furthermore, by leveraging the noted off-axis configuration, various embodiments of the present disclose allows for increased pole count (e.g., allows for more poles to be packaged in the magnet), higher resolution, and larger magnet diameter, and scalability. Moreover, various embodiments improve electrification by providing non-contact sensing, cost-effective, and compact design, which in turn results in low power.

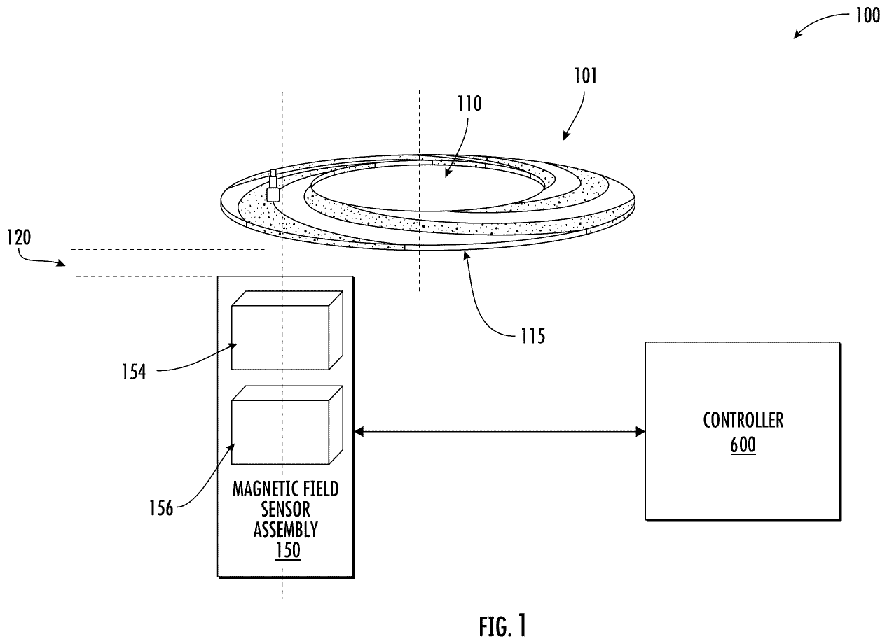

FIG. 1 schematically depicts an example off-axis multi-turn position measurement system 100 according to various embodiments of the present invention. In various embodiments, the example off-axis multi-turn position measurement system 100 includes a magnet 101 and at least one magnetic field sensor assembly 150. The off-axis multi-turn position measurement system 100 may also include a controller 600 in communication with the at least one magnetic field sensor assembly 150. In various embodiments, a magnetic field sensor assembly 150 includes an angle position sensor 154 and a multi-turn magnetoresistive sensor 156.

In various embodiments, the magnet 101 defines at least one surface 115 (e.g., magnetic surface) having magnetized tracks (e.g., magnetized poles) and also defines an opening 110. For example, the magnet 101 may have a circular profile with an opening therethrough. In various embodiments, the opening 110 may be leveraged to facilitate mounting of the magnet 101 on a rotatable component, such as a rotation shaft (e.g., steering wheel shaft, cam shaft, or the like). For example, the opening 110 may be configured for receiving at least a portion of the rotatable component. The magnet 101 may be mounted on the rotatable component via the opening 110, such that the magnet 101 surrounds at least a portion of the rotatable component. In various embodiments, the magnet 101 is configured to generate a magnetic field that is leveraged to determine the angle position and/or the turn count (e.g., number of revolutions) of the rotatable component.

In various embodiments, and as shown in FIG. 1, the magnet 101 and an example magnetic field sensor assembly 150 are positioned (e.g., during operation) relative to one another, such that the magnetic field sensor assembly 150 and the magnet 101 are off-axis with respect to each other. For example, the magnetic field sensor assembly 150 may be positioned relative to the magnet 101, such that the magnetic field sensor assembly 150 is not concentric with the axis of rotation of the magnet 101. As shown, in FIG. 1, a center of the angle position sensor 154 and a center of the multi-turn magnetoresistive sensor may not be concentric with the axis of rotation of the magnet 101. The center of the angle position sensor 154 and the center of the multi-turn magnetoresistive sensor may align with the surface 115 defined by the magnet 101. The noted off-axis configuration enables a plurality of magnetic field sensor assembly 150 to be positioned proximate to the surface 115 of the magnet 101, which provides redundancy and improves measurement accuracy (e.g., accuracy of the angle position measurement and turn count). Additionally, the noted off-axis configuration provides access to the rotatable component, which enables direct measurement.

In various embodiments, at least one magnetic field sensor assembly 150 is positioned proximate to the surface 115 of the magnet 101, such that the at least one magnetic field sensor assembly 150 is exposed to the magnetic field generated by the at least one magnetic field sensor assembly 150 during rotation of the magnet 101 about its center axis. The magnet 101 may be configured to rotate, while the at least one magnetic field sensor assembly 150 may be configured to be substantially stationary. For example, the angle position sensor 154 and/or multi-turn magnetoresistive sensor 156 may be embodied within one or more chips.

In various embodiments, the magnet 101 may be caused to rotate in response to rotational movement of the rotatable component coupled to the magnet 101. The angle position of the magnet 101 corresponding to the angle position of the rotatable component may be determined based at least in part on an output (e.g., one or more periodic position signals) generated by the angle position sensor 154 based on the direction of the magnetic field generated by the magnet 101 along the surface 115 during rotation of the magnet 101 about its center axis. In various embodiments, the magnet 101 comprises different regions of magnetic polarity, such that during relative movement of the magnet 101 with respect to the at least one magnetic field sensor assembly 150, the at least one magnetic field sensor assembly 150 passes over varying/changing magnetic field direction of the magnetic field generated by the magnet 101. In various embodiments, the angle position of the magnet 101 corresponding to the angle position of the rotatable component coupled to the magnet 101 is determined based at least in part on the varying/changing magnetic field direction of the magnet 101.

The angle position sensor 154 of a magnetic field sensor assembly 150 positioned proximate to the surface 115 of the magnet 101 may output an electrical signal (e.g., comprising one or more periodic signals) based on the varying/changing magnetic field direction in the vicinity of the angle position sensor 154 during relative rotation of the magnet 101 with respect to the angle position sensor 154. In various embodiments, the electrical signal outputted by an angle position sensor 154 may comprise sine or cosine signals.

In example embodiments, where a plurality of magnetic field sensor assemblies 150 are positioned proximate to the surface 115 of the magnet 101, the plurality of magnetic field sensor assemblies 150 may be spaced-apart along at least a portion of the path (e.g., perimeter) defined by the surface 115. In this regard, as the magnet 101 rotates about its center axis, the angle position sensor 154 of each magnetic field sensor assembly 150 is exposed to varying/changing magnetic field direction of the magnet 101 in the vicinity of the respective angle position sensor 154. Each angle position sensor 154 may generate an output signal based on the varying/changing magnetic field direction in the vicinity of the angle position sensor 154. In various embodiments, the angle position sensor provides a continuous, repeating output (e.g., sinusoidal signal) for each combination of north and south magnetic poles. In various embodiments, each output may be indicative or otherwise leveraged to determine the angle position of the rotatable component coupled to the magnet 101.

In various embodiments, the output generated by an angle position sensor 154 may be transmitted to a controller, such as controller 600. The controller may be configured to process the output (e.g., periodic position signal comprising sine or cosine signal) to determine the angle position of the rotatable component coupled to the magnet 101. In some embodiments, where the off-axis multi-turn position measurement system 100 includes a plurality of magnetic field sensor assemblies 150, the output generated by each magnetic field sensor assembly 150 may be transmitted to the controller and leveraged to provide redundancy with respect to the angle position measurement for the rotatable component.

In various embodiments, a magnetic field sensor assembly 150 may be positioned relative to and proximate to the surface 115 of the magnet 101, such that the magnet 101 (e.g., surface 115 thereof) does not come in contact with the magnetic field sensor assembly 150 during rotation of the magnet 101 about its center axis. In various embodiments, the magnet 101 and a magnetic field sensor assembly 150 may be positioned relative to and proximate to one another, such that the distance between the magnetic field sensor assembly 150 and the surface 115 of the magnet 101 define an air gap 120. The magnet 101 and the magnetic field sensor assembly 150 may be configured to maintain the air gap 120 (e.g., at least substantially maintain the air gap 120) during relative rotation of the magnet 101 with respect to the magnetic field sensor assembly 150. In various embodiments, the air gap may have a measured value that is based at least in part on the field strength of the magnet 101. In an example implementation, the air gap may be 3 mm or less. It should be understood, however, that in other embodiments, the air gap may be larger than 3 mm.

In various embodiments, an angle position sensor 154 may be configured to generate periodic position signals having N number of periods per revolution (as described further below). In various embodiments, the angle position sensor 154 comprises a magnetoresistive sensor. For example, the angle position sensor may comprise an anisotropic magnetoresistance (AMR) sensor, a giant magnetoresistance (GMR) sensor, and/or the like. In some embodiments, an angle position sensor 154 may include two interleaved or overlaid magnetoresistive (MR) Wheatstone bridge sensors. The two MR bridge sensors may be offset by 45 degrees with respect to one another, and the differential signals of these two MR bridge sensors (via comparators or operational amplifiers) may advantageously produce separate sine and cosine signals (e.g., periodic position signals phase shifted by 90 degrees). The sine and cosine signals generated by the two MR bridges tilted 45 degrees with respect to one another may be the result of relative rotation of the magnet 101 with respect to the respective angle position sensor 154, wherein the MR bridges pass over the magnet 101 having varying/changing magnetic field direction. In various embodiments, the noted sine and cosine signals may be indicative of the angle position of the rotatable component coupled to the magnet 101 or otherwise leveraged to determine the angle position of the rotatable component. In some embodiments, the sine and cosine signals may allow for extraction of the angle position based at least in part on applying an arctangent function to the sine and cosine signals.

In various embodiments, the magnet 101 is a multipole magnet having adjacent magnetized north and south tracks (e.g., adjacent magnetized north and south poles). In various embodiments, and as shown in FIG. 1, the magnet 101 may be configured as or otherwise comprise a radial spiral disk multipole magnet array.

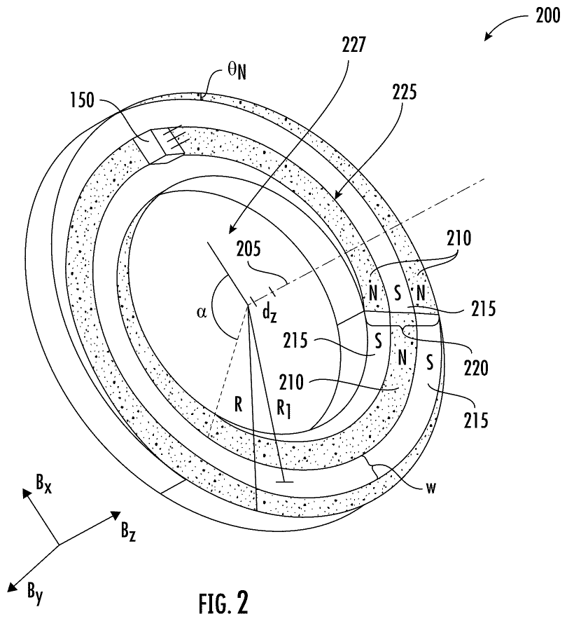

FIG. 2 depicts a perspective view of an example radial spiral disk multipole magnet array 200 with adjacent magnetized north and south tracks (e.g., adjacent magnetized north and south poles) having a tilt angle, such that the adjacent magnetized north and south tracks are oriented as a spiral shape. The example radial spiral disk multipole magnet array 200 may comprise a specific implementation of the magnet 101. The radial spiral disk multipole magnet array 200 defines a surface 225 (similar to surface 115 described above with reference to FIG. 1) comprising adjacent magnetized north and south tracks, and also defines an opening 227 (similar to opening 110 described above with reference to FIG. 1). The opening 227 may be configured to enable an off-axis configuration as described above which, in turn, allows for one or more magnetic field sensor assemblies 150 to be positioned proximate to and around the magnet 101 during rotation of the magnet 101. In this regard, one or more magnetic field sensor assemblies 150 may be positioned proximate to and around the rotatable component coupled to the radial spiral disk multipole magnet array 200), while also advantageously providing access to the rotatable component. Such access may allow for efficient and effective performance of various functionalities associated with driving the system using the rotatable component.

The radial spiral disk multipole magnet array 200 has a center axis 205 about which the radial spiral disk multipole magnet array 200 may rotate. The radial spiral disk multipole magnet array 200 is formed of magnetized north poles 210 and south poles 215. The magnetized north and south poles 210 and 215 spiral inward towards the center axis 205 (e.g., the radius Rₗ of each pole 210, 215 relative to the center axis 205 is monotonically increasing (clockwise direction) or decreasing (counterclockwise direction)). In this regard, the magnetized poles of the radial spiral disk multipole magnet array 200 wind around the center axis 205, such that the poles are monotonically disposed (e.g., located or positioned in an outward spiral) about the center axis 205 as a function of the radial angle α about the center axis 205. For example, the radial width-wise mid-point of each magnetized pole may be distributed monotonically as a function of the radial angle α about the center axis 205. Each north pole 210 is adjacent to a respective magnetized south pole 215, such that the poles alternate as the radial distance from the center axis 205 increases. At magnetic discontinuity 220, the poles switch polarity, but continue to spiral within the radial spiral disk multipole magnet array 200.

As shown in FIG. 2, at least one magnetic field sensor assembly 150 is located on the surface 225 of the radial spiral disk multipole magnet array 200. The angle position sensor 154 of the magnetic field sensor assembly 150 is configured to output an electrical signal that is a function of the local magnetic field around the angle position sensor 154. As the radial spiral disk multipole magnet array 200 rotates around the center axis 205, the direction of the magnetic field around a magnetic field sensor assembly 150 proximate to the radial spiral disk multipole magnet array 200 varies/changes due to the spiral nature of the magnetized poles 210 and 215, wherein the electrical signal outputted by the angle position sensor 154 may be generated based on the changing magnetic field direction. For example, the magnetic field may vary in a sinusoidal or cosinusoidal fashion due to the tilt angle θ_{N} of the magnetized poles of the radial spiral disk multipole magnet array 200. In some examples, the magnetic discontinuity 220 may be absent from the radial spiral disk multipole magnet array 200. In various embodiments, the spiral windings in the radial spiral disk multipole magnet array 200 may have greater or lesser pitch (e.g., tilt angle θ_{N}) than the illustrative embodiment shown in FIG. 2. The pitch of the radial spiral disk multipole magnet array 200 may be customized to determine the exact period of sine/cosine signals output by the angle position sensor 154 when the radial spiral disk multipole magnet array 200 rotates at, for example, a constant angular velocity. For example, the periods of the periodic positional signal (e.g., sine and cosine periods) outputted by an angle position sensor 154 may be based at least in part on the tilt angle θ_{N}, which enables the periodic positional signal to be customized/configurable.

In various embodiments, the alternating magnetized north and south poles 210, 215 generate magnetic field lines that originate from the magnetized north pole 210 and terminate at the magnetized south pole 215. Near the center of each pole 210 and 215, the magnetic field lines are substantially orthogonal to the plane defined by the surface 225. For example, near the center of the magnetized north poles 210, the magnetic field lines point upward and normal to the plane of the surface 225. Near the center of the magnetized south poles 215, the magnetic field lines point downward and normal to the plane of the surface 225.

An angle position sensor 154 located proximate to the surface 225 of the radial spiral disk multipole magnet array 200 travels a path relative to the surface 225. A coordinate axis is defined with respect to the surface 225, with a Bₓ-axis defined by movement right and left relative to the surface 225, a B_{y}-axis defined by movement forward and backward relative to the surface 225, and a z-axis defined by movement up and down relative to the surface 225. The path of the angle position sensor 154 may not vary along the Br-axis but may moves along the Bₓ and B_{y} axes. In this regard, the path of the magnetic field sensor may be a substantially straight line that lies in a plane defined by the Bₓ and B_{y} axes for a constant z value above the surface 225. The line of the path may make an angle θ with respect to the Bₓ-axis. Relative constant movement of the angle position sensor with respect to the surface 225 may results in a sinusoidal signal output by the angle position sensor. In various embodiments, the period P_{θ} of the sinusoidal signal is dependent in part upon the period p of the pattern of the magnetized north and south poles 210 and 215 that is linked to the width w of the magnetized north and south poles 210 and 215, as well as the angle θ the path makes with respect to the Bₓ-axis:

$${P}_{θ} = \frac{w}{cos θ}$$

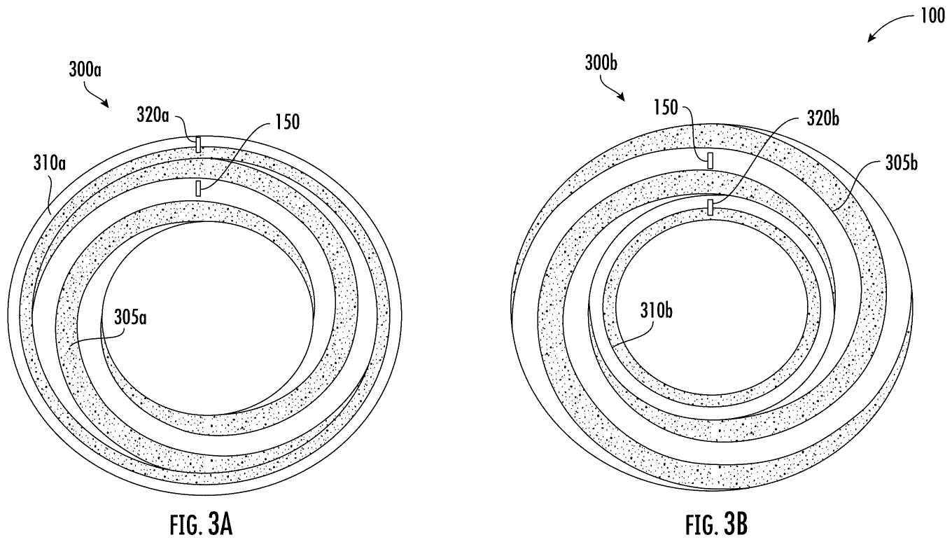

FIGS. 3A and 3B depict plan views of example radial spiral disk multipole magnet array with three adjacent magnetized north and south tracks having a tilt angle, such that the adjacent magnetized north and south tracks are oriented as a spiral shape. In the illustrated example of FIG. 3A, the radial spiral disk multipole magnet array 300a includes an outer concentric north and south poles. In the illustrated example of FIG. 3B, the radial spiral disk multipole magnet array 300b includes inner concentric north and south poles. It should be understood that in some embodiments, the radial spiral disk multipole magnet array 300a may not include an outer concentric north and south poles and/or the radial spiral disk multipole magnet array 300b may not include inner concentric north and south poles. The example radial spiral disk multipole magnet arrays of FIGS. 3A and 3B are shown along with example multi-turn magnetic field sensors 150.

FIG. 3A depicts a radial spiral disk multipole magnet array 300a, which includes three adjacent tilted spiraled poles in a spiraled magnetized pole section 305a. Circumscribing the spiraled magnetized pole section 305a are concentric magnetized north and south pole sections 310a. The concentric magnetized north and south pole sections 310a may not have the form of spiral, but rather forms concentric circles on the outer perimeter of the radial spiral disk multipole magnet array 300a. These two concentric tracks may be used to monitor and compensate for measurement error due to the radial displacement induced by stack tolerances and ageing. At least one magnetic field sensor assembly 150 comprising an angle position sensor is located proximate to the surface of the spiraled magnetized pole section 305a. The angle position sensor detects the variation of the magnetic field direction as the radial spiral disk multipole magnet array 300a rotates about its center axis. An off-axis misalignment magnetic field sensor 320a may be located proximate to the surface of the concentric magnetized north and south pole section 310a. The off-axis misalignment magnetic field sensor 320a may be used to detect and to compensate for the off-axis rotation/oscillation/movement of the radial spiral disk multipole magnet array 300a.

FIG. 3B depicts a radial spiral disk multipole magnet array 300b, which includes a spiraled magnetized pole section 305b. Within the spiraled magnetized pole section 305b is a concentric magnetized north and south pole section 310b. The concentric magnetized north and south pole section 310b may not have the form of spiral, but rather forms concentric circles on the inner perimeter of the second radial spiral disk multipole magnet array 300b. At least one magnetic field sensor assembly 150 comprising an angle position sensor is located proximate a surface of, and in the middle of the spiraled magnetized pole section 305b, while an off-axis misalignment magnetic field sensor 320b is located proximate a surface of the concentric magnetized north and south pole section 310b. The angle position sensor detects the variation of the magnetic field direction as the radial spiral disk multipole magnet array 300b rotates about its center axis. The off-axis misalignment magnetic field sensor 320b may be used to detect and to compensate for the off-axis rotation/oscillation/movement of the radial spiral disk multipole magnet array 300b.

While FIGS. 1-3B depict an example radial spiral disk multipole magnet array with three magnetized tracks, an example radial spiral disk multipole magnet array according to various embodiments may have less than three magnetized tracks or more than three magnetized tracks. A radial spiral disk multipole magnet array has described herein may be characterized by pole count. In various embodiments, a pole count may describe the number of alternating south and north poles. In various embodiments, the number of periods per revolution of the radial spiral disk multipole magnet array 200 may be based on the pole count.

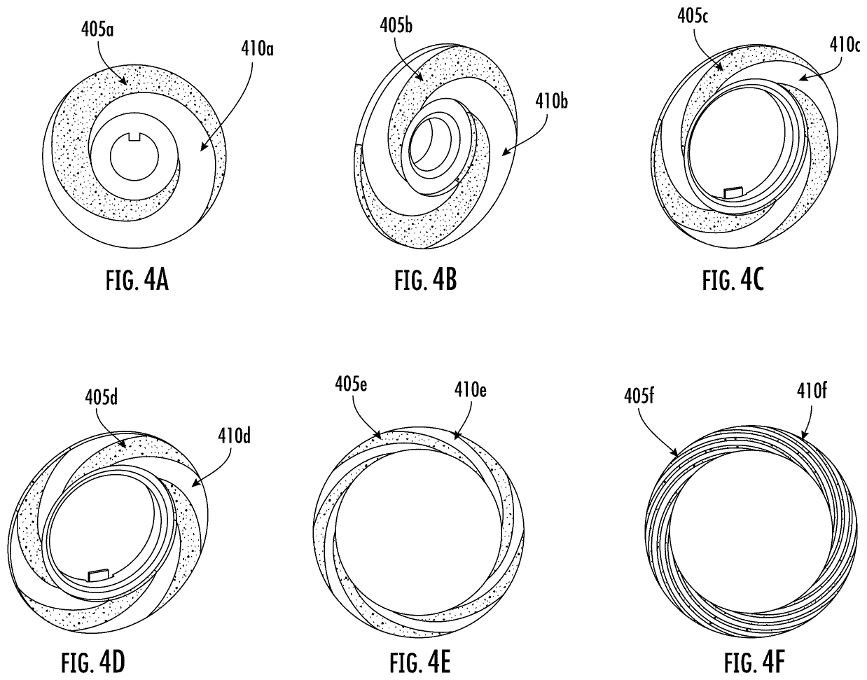

FIGS. 4A-4F depict example radial spiral disk multipole magnet array having different pole counts. FIG. 4A depicts a radial spiral disk multipole magnet array 400A having two poles (e.g., “two pole” radial spiral disk multipole magnet array). The radial spiral disk multipole magnet array 400A is formed of adjacent tilted and alternating magnetized north and south poles 405a, 410a having the same width w being tapered off into infinitesimal slices moving along the radial spiral disk multipole magnet array 400A. FIG. 4B depicts a radial spiral disk multipole magnet array 400B having four poles (e.g., “four pole” radial spiral disk multipole magnet array). The radial spiral disk multipole magnet array 400B is formed of adjacent tilted and alternating magnetized north and south poles 405b, 410b having the same width w being tapered off into infinitesimal slices moving along the radial spiral disk multipole magnet array 400B. FIG. 4C depicts a radial spiral disk multipole magnet array 400C having six poles (e.g., “six pole” radial spiral disk multipole magnet array). The radial spiral disk multipole magnet array 400C is formed of adjacent tilted and alternating magnetized north and south poles 405c, 410c having the same width w being tapered off into infinitesimal slices moving along the radial spiral disk multipole magnet array 400C. FIG. 4D depicts a radial spiral disk multipole magnet array 400D having eight poles (e.g., “eight pole” radial spiral disk multipole magnet array). The radial spiral disk multipole magnet array 400D is formed of adjacent tilted and alternating magnetized north and south poles 405d, 410d having the same width w being tapered off into infinitesimal slices moving along the radial spiral disk multipole magnet array 400D. FIG. 4E depicts a radial spiral disk multipole magnet array 400E having ten poles (e.g., “ten pole” radial spiral disk multipole magnet array). The radial spiral disk multipole magnet array 400E is formed of adjacent tilted and alternating magnetized north and south poles 405e, 410e having the same width w being tapered off into infinitesimal slices moving along the radial spiral disk multipole magnet array 400E. FIG. 4F depicts a radial spiral disk multipole magnet array 400F having twenty-four poles (e.g., “twenty-four pole” radial spiral disk multipole magnet array). The radial spiral disk multipole magnet array 400F is formed of adjacent tilted and alternating magnetized north and south poles 405f, 410f having the same width w being tapered off into infinitesimal slices moving along the radial spiral disk multipole magnet array 400F.

It should be understood that a radial spiral disk multipole magnet array as described herein is not limited to the pole count configurations of the examples provided in FIGS. 4A-4F. In various embodiments, a radial spiral disk multipole magnet array may have a pole count that is different from the examples of FIGS. 4A-4F. For example, an example radial spiral disk multipole magnet array may comprise 7 poles, 9 poles, or the like in some embodiments. In various embodiments, the pole count can be adjusted and/or selected to create N periods per revolution of a radial spiral disk multipole magnet array to, for example, obtain absolute position measurement within each of the N periods. For example, an electrical motor with four poles (N=4) may use a four-pole radial spiral multipole magnet array to create 4 periods per revolution. In another example, an electrical motor with sixteen poles (N=16) may use a sixteen-pole radial spiral disk multipole magnet array to create 16 periods per revolution. In this regard, the number of poles of the radial spiral disk multipole magnet array may be advantageously tailored to a specific type of electrical motor having a specific number of poles. The magnetic field generated by the radial spiral disk multipole magnet array may vary in a sinusoidal or cosinusoidal fashion, wherein an angle position sensor may generate an output signal with a N periods per revolution, wherein N is based on the pole count of the radial spiral disk multipole magnet array.

In various embodiments, a radial spiral disk multipole magnet array may have a spiral in a number of poles (e.g., 2, 6, 8, 24, 36 or the like) for the required angle. In various embodiments, the pole count of a radial spiral disk multipole magnet array may be based at least in part on the tilt angle of the north and south poles and/or the width of the north and south poles. Additionally and/or alternatively, in various embodiments, the pole count of the radial spiral disk multipole magnet array may be based at least in part on one or more other parameters (e.g., outer diameter, inner diameter, radial thickness, axial thickness, and/or the like) of the radial spiral disk multipole magnet array. In various embodiments, the pole pattern is an Archimedean spiral that is generally defined as r=a+b·θ^{(l/c)}, where r is the radius at a given angle θ (e.g., amount of rotation of the radius), a is the starting location of the spiral at the inner diameter, b is the tilt angle, and c describes the growth rate/shape of the radius.

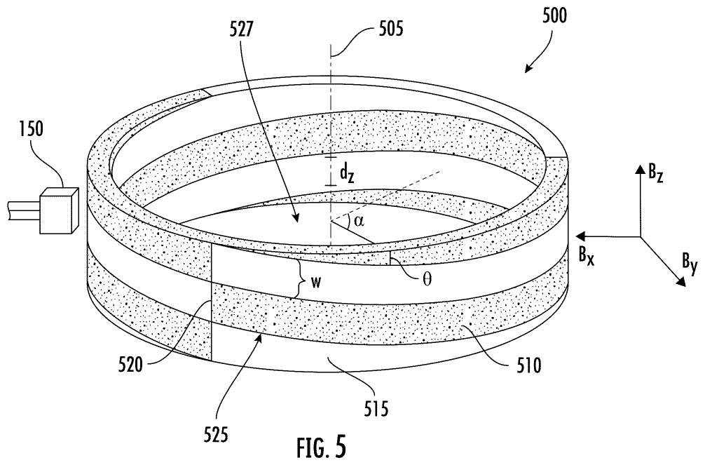

FIG. 5 depicts a perspective view of an example axial cylindrical helical multipole magnet array configuration. Specifically, FIG. 5 depicts an axial cylindrical helical multipole magnet array 500 with three adjacent magnetized tilted tracks (e.g., adjacent magnetized tilted poles). The example axial cylindrical helical multipole magnet array 500 may comprise a specific implementation of the magnet 101. The axial cylindrical helical multipole magnet array 500 defines a surface 525 comprising adjacent magnetized north and south tracks, and also defines an opening 527. The opening 527 may be configured to enable an off-axis configuration as described above which, in turn, enables one or more magnetic field sensor assembly 150 to be positioned around the axial cylindrical helical multipole magnet array 500 (thus around the rotatable component coupled to the axial cylindrical helical multipole magnet array 500) during rotation of the axial cylindrical helical multipole magnet array 500, while also advantageously providing access to the rotatable component.

The axial cylindrical helical multipole magnet array 500 is shown having a center axis 505. The axial cylindrical helical multipole magnet array 500 may rotate around the center axis 505 when, for example, the axial cylindrical helical multipole magnet array 500 is coupled to a rotatable component (e.g., rotating shaft). The axial cylindrical helical multipole magnet array 500 includes three adjacent magnetized poles. These magnetized poles include a north magnetized pole 510 and a south magnetized pole 515 that are adjacent to one another and have a fixed width w. The magnetized poles 510 and 515 coil within the axial cylindrical helical multipole magnet array 500 in a helical fashion with a constant tilted angle. The magnetized poles 510 and 515 wind around the center axis 505, such that the magnetized poles are monotonically disposed (e.g., located or distributed in a circular helix/helicoid configuration having a constant magnitude slope) about the center axis 505 as a function of the radial angle α about the center axis 505, as well as the distance d_{z} along the center axis 505. In this regard, the width-wise mid-point of each magnetized pole is distributed monotonically as a function of the radial angle α (e.g., moving from 0° to 360°) about the center axis 505, as well as the distance d_{z} along the center axis 505. At magnetic discontinuity 520, the poles switch polarity, but continue to coil within the axial cylindrical helical multipole magnet array 500. While FIG. 5 depicts an example axial cylindrical helical multipole magnet array 500 with three magnetized tracks, an example axial cylindrical helical multipole magnet array 500 according to various embodiments may have less than three magnetized tracks or more than three magnetized tracks.

As shown in FIG. 5, at least one magnetic field sensor assembly 150 comprising an angle position sensor is located proximate to the surface 525 of the axial cylindrical helical multipole magnet array 500. The angle position sensor is configured to output an electrical signal that is a function of the local magnetic field around the angle position sensor. As the example axial cylindrical helical multipole magnet array 500 rotates around the center axis 505, the direction of the magnetic field around the angle position sensor vary due to the helical nature of the magnetized poles 510 and 515, wherein the electrical signal outputted by the angle position sensor is generated based on the changing magnetic field direction. For example, the magnetic field may vary in a sinusoidal or cosinusoidal fashion due to the tilt angle of the magnetized poles of the axial cylindrical helical multipole magnet array 500. In some examples, the magnetic discontinuity 520 may be absent from the axial cylindrical helical multipole magnet array 500. In various embodiments, the helical windings in the axial cylindrical helical multipole magnet array 500 may have greater or lesser pitch θ than the illustrative embodiment shown in FIG. 5. The pitch of the axial cylindrical helical multipole magnet array 500 may be customized to determine the exact period of sine/cosine signals output by an angle position sensor 154 when the axial cylindrical helical multipole magnet array 500 rotates at, for example, a constant angular velocity.

As described above with reference to FIG. 1, the magnetic field sensor assembly 150 may include a multi-turn magnetoresistive sensor 156. The example multi-turn magnetoresistive sensor may be leveraged to determine the number of turns associated with rotatable component. The example multi-turn magnetoresistive sensor 156 may be embodied as a multi-turn magnetoresistive sensor chip. The example multi-turn magnetoresistive sensor 156 may be configured to enable multi-turn true power off position sensing that obviates the need for complex configurations, such as complex gear trains. The multi-turn magnetoresistive sensor 156 may use domain wall technology to achieve the multi-turn count. For example, the example multi-turn magnetoresistive sensor 156 may be configured to determine the number of turns (e.g., number of revolutions) a rotatable component has made based on a magnetic state(s) associated with the turns of the magnetic field generated by the magnet 101 (e.g., radial spiral disk multipole array described with reference to FIGS. 1-4, helical multipole magnet array described with reference to FIG. 5). The multi-turn magnetoresistive sensor may be configured to provide discrete steps output or a continuous output.

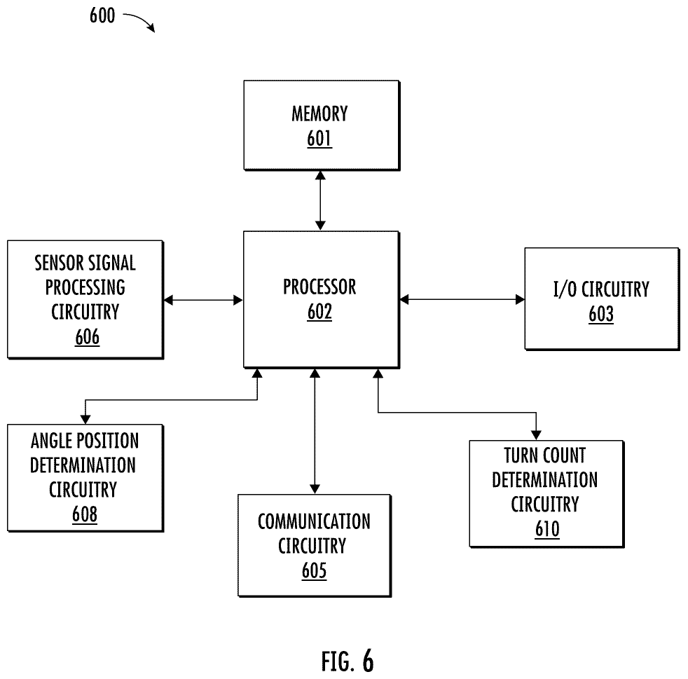

In various embodiments, the off-axis multi-turn position measurement system 100 may be communicably coupled to one or more controllers, such as controller 600 depicted in FIG. 6. As depicted in FIG. 6, the controller 600 may comprise a memory 601, a processor 602, input/output circuitry 603, communication circuitry 605, sensor signal processing circuitry 606, angle position determination circuitry 608, and turn count determination circuitry 610. The controller 600 may be configured to execute one or more of the various operations described herein. Although the components are described with respect to functional limitations, it should be understood that the particular implementations necessarily include the use of particular hardware. It should also be understood that certain of the components described herein may include similar or common hardware. For example, two sets of circuitry may both leverage use of the same processor, network interface, storage medium, or the like to perform their associated functions, such that duplicate hardware is not required for each set of circuitry. The use of the term “circuitry” as used herein with respect to components of the controller 600 should therefore be understood to include particular hardware configured to perform the functions associated with the particular circuitry as described herein.

The term “circuitry” should be understood broadly to include hardware and, in some embodiments, software for configuring the hardware. For example, in some embodiments, “circuitry” may include processing circuitry, storage media, network interfaces, input/output devices, and the like. In some embodiments, other elements of the controller 600 may provide or supplement the functionality of particular circuitry. For example, the processor 602 may provide processing functionality, the memory 601 may provide storage functionality, the communication circuitry 605 may provide network interface functionality, and the like.

In some embodiments, the processor 602 (and/or co-processor or any other processing circuitry assisting or otherwise associated with the processor) may be in communication with the memory 601 via a bus for passing information among components of the apparatus. The memory 601 may be non-transitory and may include, for example, one or more volatile and/or non-volatile memories. For example, the memory 601 may be an electronic storage device (e.g., a computer readable storage medium). In various embodiments, the memory 601 may be configured to store information, data, content, applications, instructions, or the like, for enabling the apparatus to carry out various functions in accordance with example embodiments of the present disclosure. It will be understood that the memory 601 may be configured to store partially or wholly any electronic information, data, data structures, embodiments, examples, figures, processes, operations, techniques, algorithms, instructions, systems, apparatuses, methods, look-up tables, or computer program products described herein, or any combination thereof.

The processor 602 may be embodied in a number of different ways and may, for example, include one or more processing devices configured to perform independently. Additionally or alternatively, the processor may include one or more processors configured in tandem via a bus to enable independent execution of instructions, pipelining, and/or multithreading. The use of the term “processing circuitry” may be understood to include a single core processor, a multi-core processor, multiple processors internal to the apparatus, and/or remote or “cloud” processors.

In an example embodiment, the processor 602 may be configured to execute instructions stored in the memory 601 or otherwise accessible to the processor. Alternatively, or additionally, the processor may be configured to execute hard-coded functionality. As such, whether configured by hardware or software methods, or by a combination thereof, the processor may represent an entity (e.g., physically embodied in circuitry) capable of performing operations according to an embodiment of the present disclosure while configured accordingly. Alternatively, as another example, when the processor is embodied as an executor of software instructions, the instructions may specifically configure the processor to perform the algorithms and/or operations described herein when the instructions are executed. For example, in various embodiments, the processor 602 may comprise drive circuitry. For example, the drive circuitry may be configured to generate a signal defined at least in part by one or more predetermined signal characteristics, such as, for example, a signal frequency.

In some embodiments, the controller 600 may include input/output circuitry 603 that may, in turn, be in communication with the processor 602 to provide output to the user and, in some embodiments, to receive input such as a command provided by the user. The input/output circuitry 603 may comprise a user interface, such as a graphical user interface (GUI), and may include a display that may include a web user interface, a GUI application, a mobile application, a client device, or any other suitable hardware or software. In some embodiments, the input/output circuitry 603 may also include a display device, a display screen, user input elements, such as a touch screen, touch areas, soft keys, a keyboard, a mouse, a microphone, a speaker (e.g., a buzzer), a light emitting device (e.g., a red light emitting diode (LED), a green LED, a blue LED, a white LED, an infrared (IR) LED, an ultraviolet (UV) LED, or a combination thereof), or other input-output mechanisms. The processor 602, input/output circuitry 603 (which may utilize the processing circuitry), or both may be configured to control one or more functions of one or more user interface elements through computer-executable program code instructions (e.g., software, firmware) stored in a non-transitory computer-readable storage medium (e.g., memory 601). Input/output circuitry 603 is optional and, in some embodiments, the controller 600 may not include input-output circuitry. For example, where the controller 600 does not interact directly with the user, the controller 600 may generate user interface data for display by one or more other devices with which one or more users directly interact and transmit the generated user interface data to one or more of those devices. For example, the controller 600, using user interface circuitry may generate user interface data for display by one or more display devices and transmit the generated user interface data to those display devices.

The communication circuitry 605 may be a device or circuitry embodied in either hardware or a combination of hardware and software that is configured to receive and/or transmit data from/to a network and/or any other device, circuitry, or module in communication with the off-axis multi-turn position measurement system 100. For example, the communication circuitry 605 may be configured to communicate with one or more computing devices via wired (e.g., USB) or wireless (e.g., Bluetooth, Wi-Fi, cellular, and/or the like) communication protocols.

In various embodiments, the processor 602 may be configured to communicate with the angle position determination circuitry 608. The angle position determination circuitry 608 may be a device or circuitry embodied in either hardware or a combination of hardware and software that is configured to execute an angle position determination operation of an example off-axis multi-turn position measurement system as described herein. In various embodiments, the angle position determination circuitry 608 may be configured to determine the position of a rotatable component based at least in part on the output signal generated by an angle position sensor in response to rotation of a magnet coupled to the rotatable component along the magnet's center axis. In various embodiments, the angle position determination circuitry 608 may be configured to determine angle position data (e.g., comprising angle position), based at least in part on output of an angle position sensor, wherein the output may be generated based at least in part on exposure of the angle position sensor to varying/changing magnetic field direction of a magnet having alternating magnetic polarity on a surface thereof.

In some embodiments, the angle position determination circuitry 608 may be configured to transmit angle position data (e.g., comprising angle position) of a rotatable component to one or more control systems associated with the rotatable component, wherein the angle position data may be indicative of the position of the rotatable component along a path of the rotatable component, and wherein the angle position data may be used to control various operations and/or parameters of the rotatable component and/or components, devices, systems, and/or the like that may be associated with the rotatable component.

In various embodiments, the angle position data for a rotatable component may be generated based at least in part on determining (e.g., calculating) the arctangent of the periodic position signal data generated by an angle position sensor. In various embodiments, the angle position determination circuitry may be configured to translate the angle position data for a rotatable component into a control output signal that may be transmitted to a control system associated with the rotatable component, such that the control system may control one or more parameters (e.g., speed, movement, position, and/or the like) of the rotatable component and/or other components, devices, and/or the like associated with the rotatable component. In some embodiments, the angle position determination circuitry 608 may be configured to convert digital signal to an analog signal. In some embodiments, the angle position determination circuitry 608 may be configured to convert analog signal to digital signal.

In various embodiments, the processor 602 may be configured to communicate with the turn count determination circuitry 610. The turn count determination circuitry 610 may be a device or circuitry embodied in either hardware or a combination of hardware and software that is configured to execute a turn count sensing operation of an exemplary off-axis multi-turn position measurement system as described herein. In various embodiments, the turn count determination circuitry 610 may be configured to determine the turn count of a rotatable component based at least in part on the output generated by a multi-turn magnetoresistive sensor in response to rotation of the magnet coupled to the rotatable component.

In various embodiments, the turn count determination circuitry 610 may be configured to transmit turn count data (e.g., comprising turn count) of a rotatable component to one or more control systems associated with the rotatable component, wherein the turn count data may be indicative of the number of turns (e.g., number of revolutions) of the rotatable component, wherein the turn count data may be used to control various operations and/or parameters of the rotatable component and/or components, devices, systems, and/or the like that may be associated with the rotatable component.

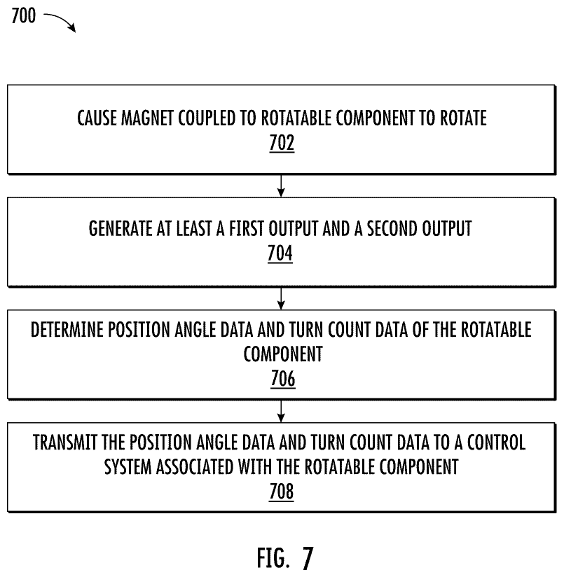

FIG. 7 depicts an example process 700 of an example method of determining the angle position and turn count of a rotatable component in accordance with one or more embodiments of the present invention. The process that is depicted in FIG. 7 may begin at step/operation 702, when a magnet (such as magnet 101 comprising a radial spiral disk multipole magnet array or axial cylindrical helical multipole magnet array) coupled to the rotatable component is caused to rotate about its center axis relative to a magnetic field sensor assembly (such as magnetic field sensor assembly 150). In some embodiments, a controller (such as controller 600) may directly or indirectly cause the magnet to rotate. For example, the controller may cause a rotatable component coupled to the magnet to rotate, which in turn causes the magnet to rotate. Additionally and/or alternatively, in some embodiments, one or more other controllers may cause the magnet to rotate.

In various embodiments, the at least one magnetic field sensor assembly is positioned proximate to a magnetic surface of the magnet such that the at least one magnetic field sensor assembly is off-axis with respect to a center axis defined by the magnet. In various embodiments, the magnetic surface comprise alternating magnetic polarities (e.g., alternating north and south magnetized poles). The at least one magnetic field sensor assembly may be positioned relative to the magnet, such that the at least one magnetic field sensor assembly and the magnet define an air gap (e.g., the distance between a magnetic field sensor assembly and the magnet may define an air gap). In various embodiments, the magnet may be coupled to the rotatable component via an opening defined by the magnet.

At step/operation 704, at least a first output and a second output are generated, using the at least one magnetic field sensor assembly and based at least in part on the relative rotation of the magnet with respect to the at least one magnetic field sensor assembly. The magnet may generate a magnetic field having varying/changing magnetic field direction based on the alternating magnetic polarities on the magnetic surface of the magnet. In various embodiments, the magnetic field sensor assembly includes an angle position sensor configured to generate the first output. In various embodiments, the first output comprises one or more periodic signals (e.g., sine and/or cosine signal) generated based on the varying/changing magnetic field direction of the magnetic field generated by the magnet. For example, the angle position sensor may generate the first output based at least in part on varying/changing magnetic fields generated by the magnet in the vicinity of the angle position sensor during the relative rotation of the magnet with respect to the angle position sensor.

In various embodiments, the magnetic field sensor assembly includes a multi-turn magnetoresistive sensor configured to generate the second output. In various embodiments, the second output comprises data determined based on the magnetic field generated by the magnet, wherein the data may be leveraged to determine the turn count of the rotatable component. In some examples, the data comprises magnetic state(s) associated with the turns of the magnetic field generated by the magnet. In various embodiments, the magnetic field sensor assembly may transmit the outputs generated by the magnetic field sensor assembly to the controller.

At step/operation 706, the controller receives the outputs transmitted by the magnetic field sensor assembly and determines (e.g., using the angle position determination circuitry), the angle position and turn count of the rotatable component. In some embodiments, the controller (using the sensor signal processing circuitry 606) may perform various signal processing functions on the received outputs from the magnetic field sensor assembly. Examples of such signal processing functions that may be performed by the sensor signal processing circuitry 606 may include stochastic filtering, sampling, digital signal processing, statistical operations, spectral analysis, time-frequency/series analysis, thresholding, digital to analog (D/A) conversion, analog to digital (D/A) conversion, and/or data transformation.

In various embodiments, the controller determines the angle position based on the first output (e.g., comprising one or more periodic position signals). In various embodiments, determining the angle position of the rotatable component based on the first output comprises extracting the angle position data for the rotatable component from the periodic position signal (e.g., sine and/or cosine signal). In various embodiments, the controller (e.g., using the angle position determination circuitry), may extract the angle position data for the rotatable component based at least in part on calculating the arctangent of the periodic position signal(s). In various embodiments, the controller (e.g., using the turn count determination circuitry) determines the turn count based on the second output. In some examples, to determine the turn count the controller e.g., using the turn count determination circuitry) processes the magnetic state(s) to extract the turn count.

At step/operation 708, the controller transmits the angle position data and turn count data for the rotatable component to one or more control systems associated with the rotatable component, wherein the angle position data and/or the turn count data may be used to control various operations and/or parameters of the rotatable component and/or components, devices, systems, and/or the like that associated with the rotatable component. For example, in some embodiments, the controller may be configured to translate the angle position data and/or turn count data for a rotatable component into control output signal(s) that may be transmitted to a control system associated with the rotatable component, such that the control system may control one or more parameters (e.g., speed, movement, position, and/or the like) of the rotatable component and/or other components, device, and/or the like associated with the rotatable component.

Although various embodiments have been described with reference to the Figures, other embodiments are possible. For example, the magnet may comprise an arc magnet array. The arc magnet array may be configured such that the top surface and/or bottom surface thereof has a topology (e.g., pole pattern) that is similar to a surface of the magnet 101 describe herein. For example, in some embodiments, magnet may define an arc of desired arc angle (e.g., arc measure), and comprise magnetized poles, each pole of the magnetized poles being adjacent to at least one oppositely magnetized pole. The magnetized poles may be oriented in a radial spiral relative to a center axis of the arc-shaped magnet, such that each magnetized pole is disposed at a radial distance from the center axis that increases as a function of increasing radial angle relative to the center axis. In some example the magnetized pole may be oriented in a helical pattern relative to a center axis of the arch-shaped magnet.

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. An off-axis multi-turn position measurement system comprising;
a magnet defining (i) a magnetic surface comprising at least two magnetized poles arranged in a spiral pattern and (ii) an opening for receiving a rotatable component, wherein the magnet generates a magnetic field having varying magnetic field direction based on the spiral pattern of the magnet; and
at least one magnetic field sensor assembly positioned proximate to the magnetic surface of the magnet such that the at least one magnetic field sensor assembly is off-axis with respect to a center axis defined by the magnet, wherein:
the magnet is rotatable about the center axis relative to the at least one magnetic field sensor assembly,
the at least one magnetic field sensor assembly is configured to generate at least a first output and a second output based on the magnetic field generated by the magnet,
an angle position of the rotatable component is determined based on the first output, and
a turn count of the rotatable component is determined based on the second output.

2. The off-axis multi-turn position measurement system of claim 1, wherein the at least one magnetic field sensor assembly comprises an angle position sensor configured to generate the first output and a multi-turn magnetoresistive sensor configured to generate the second output.

3. The off-axis multi-turn position measurement system of claim 1, wherein the angle position sensor comprises a magnetoresistive sensor.

4. The off-axis multi-turn position measurement system of claim 1, wherein the first output comprises a periodic position signals having N number of periods per revolution of the magnet.

5. The off-axis multi-turn position measurement system of claim 4, wherein the magnet as M number of pole counts, wherein the N number of periods is based on one or more of the M number of pole counts or tilt angle of the at least two magnetized poles.

6. The off-axis multi-turn position measurement system of claim 1, wherein the at least one magnetic field sensor assembly comprises a plurality of magnetic field sensor assemblies that are spaced apart around relative to and proximate to the magnetic surface of the magnet.

7. The off-axis multi-turn position measurement system of claim 1, wherein the at least one magnetic field sensor assembly is configured to be substantially stationary.

8. The off-axis multi-turn position measurement system of claim 7, wherein the at least one magnetic field sensor assembly is positioned proximate to the magnetic surface of the magnet such that the at least one magnetic field sensor assembly maintains a substantially constant air gap with respect to the magnetic surface during relative rotation of the magnet with respect to the at least one magnetic field sensor assembly.

9. The off-axis multi-turn position measurement system of claim 1, wherein the rotatable component comprises a rotatable shaft.

10. The off-axis multi-turn position measurement system of claim 1, further comprising a controller, wherein the first output and the second output of the at least one magnetic field sensor assembly is transmitted to the controller, and wherein the controller is configured to process the first output to determine the angle position and process the second output to determine the turn count.

11. The off-axis multi-turn position measurement system of claim 1, wherein the at least two magnetized poles comprise alternating magnetic polarities.

12. The off-axis multi-turn position measurement system of claim 1, wherein the at least two magnetized poles have the same width.

13. An off-axis multi-turn position measurement system comprising;
a magnet defining (i) a magnetic surface comprising at least two magnetized poles arranged in a helical pattern and (ii) an opening for receiving a rotatable component, wherein the magnet generates a magnetic field having varying magnetic field direction based on the helical pattern of the magnet; and
at least one magnetic field sensor assembly positioned proximate to the magnetic surface of the magnet such that the at least one magnetic field sensor assembly is off-axis with respect to a center axis defined by the magnet, wherein:
the magnet is rotatable about the center axis relative to the at least one magnetic field sensor assembly,
the at least one magnetic field sensor assembly is configured to generate at least a first output and a second output based on the magnetic field generated by the magnet,
an angle position of the rotatable component is determined based on the first output, and
a turn count of the rotatable component is determined based on the second output.

14. The off-axis multi-turn position measurement system of claim 13, wherein the at least one magnetic field sensor assembly comprises an angle position sensor configured to generate the first output and a multi-turn magnetoresistive sensor configured to generate the second output.

15. The off-axis multi-turn position measurement system of claim 13, wherein the angle position sensor comprises a magnetoresistive sensor.

16. The off-axis multi-turn position measurement system of claim 13, wherein the first output comprises a periodic position signals having N number of periods per revolution of the magnet.

17. The off-axis multi-turn position measurement system of claim 16, wherein the magnet as M number of pole counts, wherein the N number of periods is based on one or more of the M number of pole counts or tilt angle of the at least two magnetized poles.

18. A method for determining angle position and turn count of a rotatable component, the method comprising:
causing a magnet coupled to the rotatable component to rotate about a center of axis of the magnet relative to at least one magnetic field sensor assembly, wherein the magnet is coupled to the rotatable component via an opening defined by the magnet, and wherein the at least one magnetic field sensor assembly is configured to generate a first output and a second output based on a magnetic field generated by the magnet; and
determining, based at least in part on the first output and the second output generated by the at least one magnetic field sensor assembly, angle position data and turn count data of the rotatable component.

19. The method of claim 18, wherein the magnet comprises at least two magnetized poles arranged in a spiral pattern.

20. The method of claim 18, wherein the magnet comprises at least two magnetized poles arranged in a helical pattern.
